(19) United States
(12) Patent Application Publication
(10) Pub. No.: US 2025/0357386 A1
(43) Pub. Date: Nov. 20, 2025

(54) SEMICONDUCTOR STRUCTURE, AND SEMICONDUCTOR DEVICE AND FORMING METHOD THEREFOR

(71) Applicant: CXMT Corporation, Hefei City (CN)

(72) Inventor: CHIH-CHENG LIU, Hefei City (CN)

(73) Assignee: CXMT Corporation, Hefei City (CN)

(21) Appl. No.: 19/220,363

(22) Filed: May 28, 2025

Related U.S. Application Data
(63) Continuation of application No. PCT/CN2024/126302, filed on Oct. 22, 2024.

(30) Foreign Application Priority Data
May 20, 2024 (CN) 202410644060.0

(51) Int. Cl. H01L 23/64; H01L 21/48; H01L 23/498

(52) U.S. Cl. CPC H01L 23/642; H01L 21/4846; H01L 23/49838

(57) ABSTRACT

A semiconductor structure, and a semiconductor device and a forming method therefor are provided. The semiconductor structure includes: a substrate; first trench groups located in the substrate, wherein at least two first trench groups are arranged in a second direction, and each of the first trench groups comprises first trenches; and communication trench portions communicating with adjacent first trenches in a third direction, wherein the second direction and the third direction form an included angle.

### CROSS-REFERENCE TO RELATED APPLICATIONS

This application is a continuation of International Patent Application No. PCT/CN2024/126302 filed on Oct. 22, 2024, which claims priority to Chinese Patent Application No. 202410644060.0 filed on May 20, 2024. The disclosures of the above-referenced applications are hereby incorporated by reference in their entirety.

### BACKGROUND

An interposer is an intermediary for transmitting signals between chips and modules in 2.5D and 3D semiconductor packaging, and can realize interconnection between the chips and also interconnection with a package substrate. Due to high fine-pitch wiring capability and perpendicular through Si via interconnection capability, the Si interposer can meet high density I/O requirements and plays an important role in 2.5D and 3D semiconductor packaging.

To meet high computational power and speed requirements, a large number of silicon capacitors are generally required to be designed for the Si interposer, and the silicon capacitors play a crucial role in power and signal integrity, such that the power stability or high-frequency impedance characteristics of the device is ensured.

### SUMMARY

In view of the above, the present disclosure provides a semiconductor structure, and a semiconductor device and a forming method therefor.

Embodiments of the present disclosure relate to the technical field of semiconductors, and particularly, to a semiconductor structure, and a semiconductor device and a forming method therefor.

The present disclosure provides a semiconductor structure. The semiconductor includes: a substrate; first trench groups located in the substrate, where at least two first trench groups are arranged in a second direction X′, and each of the first trench groups includes first trenches; and communication trench portions each communicating with adjacent first trenches in a third direction Y, where the second direction X′ and the third direction Y form an included angle.

The present disclosure further provides a semiconductor device. The semiconductor device includes: a substrate;
first trench groups located in the substrate, where at least two first trench groups are arranged in a second direction X′, and each of the first trench groups includes a plurality of first trenches; communication trench portions communicating with adjacent first trenches in a third direction Y; second trench groups located in the substrate, where the second trench groups are arranged in a first direction X, where the second trench groups and the first trench groups are arranged in an array, and every two of the second trench groups are separated by one of the first trench groups in the first direction X; and a capacitor stack stacked on the first trench groups, the second trench groups, and the communication trench portions, where the capacitor stack extends continuously along side walls and bottom surfaces of the first trench groups, the second trench groups, and the communication trench portions. The first direction X, the second direction X′, and the third direction Y are located in a same plane, the first direction X is perpendicular to the third direction Y, the second direction X′ intersects with the first direction X and the third direction Y, and an included angle between the second direction X′ and the third direction Y is an acute angle.

The present disclosure further provides a method for forming a semiconductor device. The method includes: providing a substrate; forming first trench groups, second trench groups, and communication trench portions in the substrate; and forming a capacitor stack, where the capacitor stack is stacked on the first trench groups, the second trench groups, and the communication trench portions, and the capacitor stack extends continuously along side walls and bottom surfaces of the first trench groups, the second trench groups, and the communication trench portions.

### BRIEF DESCRIPTION OF DRAWINGS

FIG. 1A is a first top view of a semiconductor structure of the present disclosure.

FIG. 1B is a second top view of a semiconductor structure of the present disclosure.

FIG. 2 is a third top view of a semiconductor structure of the present disclosure.

FIG. 3 is a fourth top view of a semiconductor structure of the present disclosure.

FIG. 4 is a fifth top view of a semiconductor structure of the present disclosure.

FIG. 5 is a sixth top view of a semiconductor structure of the present disclosure.

FIG. 6 is a cross-sectional view of a semiconductor structure of the present disclosure.

FIG. 7 is a first cross-sectional view of a semiconductor device of the present disclosure.

FIG. 8 is a second cross-sectional view of a semiconductor device of the present disclosure.

FIG. 9A is a first top view of a semiconductor device of the present disclosure.

FIG. 9B is a second top view of a semiconductor device of the present disclosure.

FIG. 9C is a third top view of a semiconductor device of the present disclosure.

FIG. 9D is a fourth top view of a semiconductor device of the present disclosure.

FIG. 9E is a fifth top view of a semiconductor device of the present disclosure.

FIG. 10A is a first cross-sectional structural view corresponding to a method for forming a semiconductor device of the present disclosure.

FIG. 10B is a second cross-sectional structural view corresponding to a method for forming a semiconductor device of the present disclosure.

FIG. 10C is a third cross-sectional structural view corresponding to a method for forming a semiconductor device of the present disclosure.

FIG. 10D is a fourth cross-sectional structural view corresponding to a method for forming a semiconductor device of the present disclosure.

### DETAILED DESCRIPTION

The technical solutions of the present disclosure will be further elaborated below with reference to the drawings and embodiments. While exemplary implementations of the present disclosure are shown in the drawings, it should be understood that the present disclosure may be implemented in various forms and should not be limited by the embodiments set forth herein. Rather, these embodiments are provided such that the present disclosure will be more thoroughly understood and the scope of the present disclosure will be fully conveyed to those skilled in the art.

The present disclosure is more specifically described in the following paragraphs with reference to the drawings by way of example. The advantages and features of the present disclosure will become apparent from the following description and claims. It should be noted that the drawings are all in a very simplified form and not to a precise scale, and are provided only for the purpose of facilitating a convenient and clear description of the embodiments of the present disclosure.

It will be understood that the meaning of “on”, “above”, and “over” in the present disclosure should be interpreted in the broadest manner such that “on” not only includes the meaning of “on” something with no intermediate feature or layer therebetween (i.e., directly on something) but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

In the embodiments of the present disclosure, the term “layer” refers to a material portion that includes a region having a thickness. A layer may extend over the entirety of the underlying or overlying structure or may have an extent that is less than the extent of the underlying or overlying structure. Furthermore, a layer may be a region of a homogeneous or inhomogeneous continuous structure having a thickness less than the thickness of a continuous structure. For example, a layer may be located between the top surface and the bottom surface of a continuous structure, or a layer may be located between any pair of horizontal planes at the top surface and the bottom surface of the continuous structure. A layer may extend horizontally, perpendicularly, and/or along inclined surfaces. A layer may include a plurality of sub-layers.

It should be noted that unless conflicting, the technical solutions described in the embodiments of the present disclosure may be arbitrarily combined.

The silicon capacitor, used as a decoupling capacitor, mainly functions to reduce noise and decouple. Therefore, it is desirable for the capacitance density of the silicon capacitor to be maximized while minimizing the equivalent resistance and leakage current of the interconnection structure therein; meanwhile, the overall structure of the Si interposer should be reliable, with high surface flatness and minimal warpage.

Based on this, the semiconductor structure of the technical solutions of the present disclosure is described in detail below with reference to the accompanying drawings and specific embodiments.

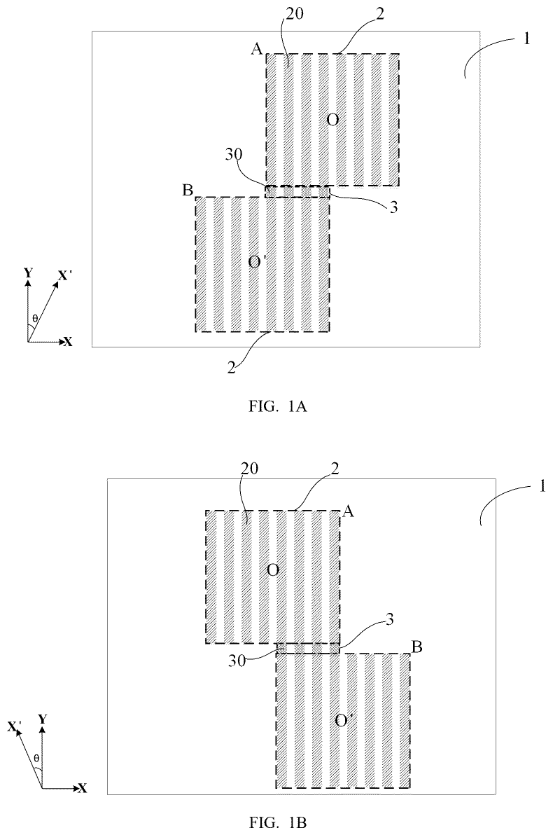

Referring to FIGS. 1A and 1B, the present disclosure provides a semiconductor structure. The semiconductor structure includes: a substrate 1; first trench groups 2 located in the substrate 1, where at least two first trench groups 2 are arranged in a second direction X′, and the first trench group 2 includes a plurality of first trenches 20; and communication trench portions 3 communicating with adjacent first trenches 20 in a third direction Y.

The substrate 1 may include, but is not limited to, a monocrystalline silicon substrate, a polycrystalline silicon substrate, a gallium nitride substrate, or a sapphire substrate. When the substrate 1 is a monocrystalline substrate or a polycrystalline substrate, the substrate may also be an intrinsic silicon substrate or a doped silicon substrate, and further may be an N-type polycrystalline silicon substrate or a P-type polycrystalline silicon substrate. The substrate 1 may include, but is not limited to, an organic substrate, a glass substrate, a ceramic substrate, or a metal substrate.

The semiconductor structure includes at least two first trench groups 2. The two first trench groups 2 are offset, the offset arrangement is parallel to the second direction X′. Referring to the top views of the semiconductor structure shown in FIGS. 1A and 1B, the connection lines between features located at the same positions on the two first trench groups 2 are parallel to the second direction X′ in the top views. As an example, the connection line between the center point O of one first trench group 2 and the center point O′ of the other first trench group 2 is parallel to the second direction X′; the center points O and O′ may be imaginary points and may not belong to the structural feature of the first trench group 2. Alternatively, the connection line between point A in the corner of one first trench group 2 and point B in the corner of the other first trench group 2 is parallel to the second direction X′.

For clarity and simplicity of the description, as shown in FIGS. 1 and 1B, the first direction X, the second direction X′, and the third direction Y are defined to be located in the same plane, the first direction X is perpendicular to the third direction Y, the second direction X′ intersects with the first direction X and the third direction Y, and an included angle θ between the second direction X′ and the third direction Y is an acute angle.

The first trench group 2 includes a plurality of first trenches 20. As an example, the first trench 20 is in the form of a rectangular trench, the plurality of first trenches 20 of each first trench group 2 are parallel to each other, and each first trench 20 extends in the third direction Y. Other embodiments are also possible for the shape and extension direction of the first trench 20; for example, the first trench 20 is in the shape of a circular arc-shaped trench (not shown), which is not limited herein.

The rectangular trench set forth in the present disclosure may be in a standard right-angled rectangular shape or a rounded-angled rectangular shape (the end or the right-angled position of the rectangle is a circular arc), or even in an approximately elliptical shape. The rectangular shape does not constitute a limitation on the trench; for example, the rectangular trench extending in the third direction Y may be the center line of the trench extending in the third direction.

The semiconductor structure further includes communication trench portions 3, and the communication trench portion 3 communicates with adjacent first trenches 20 in the third direction Y. Since at least two first trench groups 2 are offset, first trenches vertically adjacent to each other in the third direction Y are arranged at the position where the two first trench groups 2 are proximal to each other. The communication trench portion 3 includes a plurality of communication trenches 30, and the plurality of communication trenches 30 communicate with the first trenches 20 vertically adjacent to each other in the third direction Y.

The communication trench portion 3 and the communication trench 30 can ensure that the structural stress of the substrate 1 is low and the reliability thereof is high, especially the warpage of the substrate 1 in a direction perpendicular to the third direction Y is low, the surface flatness of the substrate 1 is good, and the reliability of the metal interconnection structure in the substrate 1 is high, thereby ensuring the interconnection reliability between the substrate 1 and the chip or module or other substrate packages.

Each communication trench 30 extends in the third direction Y. As an example, when each first trench 20 extends in the third direction Y, the communication trench 30 and two first trenches 20 vertically adjacent thereto in the third direction Y communicate with each other in a collinear manner and are collinearly aligned.

In one embodiment, the number of the first trenches 20 in each first trench group 2 is N, and the number of the communication trenches 30 in each communication trench portion 3 is M. The included angle θ between the second direction X′ and the third direction Y is an acute angle including zero, and when the included angle θ is zero, the number M of the communication trenches 30 is equal to the number N of the first trenches 20. In this case, two adjacent first trench groups 2 in the third direction Y are completely connected by the communication trench portion 3.

In other embodiments, the number M of the communication trenches 30 is at least a natural number 1, that is, at least one communication trench 30 communicates with two adjacent first trench groups 2 in the third direction Y. For lower structural stress and higher reliability of the substrate 1, in an optional embodiment, the number M of the communication trenches 30 is greater than or equal to N/2.

As an example, FIG. 1 only shows two adjacent first trench groups 2 in the third direction Y and the corresponding communication trench portion 3 and the communication trenches 30 thereof. The first trenches 20 extend in the third direction Y, the communication trenches 30 extend in the third direction Y, the first trenches 20 and the communication trenches 30 aligned collinearly are both rectangular trenches, and the number M of the communication trenches 30 is equal to half of the number N of the first trenches 20. However, this example does not constitute a limitation on the specific implementation.

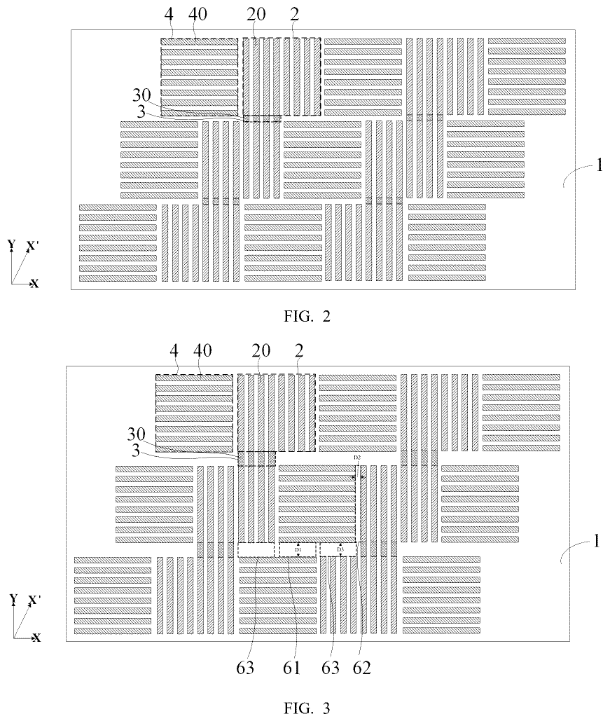

Referring to FIG. 2, the semiconductor structure provided in the present disclosure further includes: second trench groups 4 located in the substrate 1, where a plurality of second trench groups 4 are arranged in the first direction X. The second trench groups 4 and the first trench groups 2 are arranged in an array, and two second trench groups 4 arranged in the first direction X are separated by the first trench group 2; it may also be seen as that two adjacent first trench groups 2 in the first direction X are separated by the second trench group 4, and the first trench groups 2 and the second trench groups 4 are arranged in a criss-cross manner. In the embodiment, the arrangement of a plurality of first trench groups 2 is made with reference to any one of the embodiments of the semiconductor structure in FIG. 1, which will not be repeated here.

In another embodiment, the plurality of second trench groups 4 are arranged in the second direction X′ to form a second trench group array. Referring to the embodiment shown in FIG. 1, a plurality of first trench groups 2 are arranged in the second direction X′ to form a first trench group array. The first trench group arrays and the second trench group arrays are spaced apart in the first direction X, and two second trench group arrays arranged in the first direction X are separated by one first trench group array; it may also be seen that two first trench groups 2 arranged in the first direction X are separated by the second trench group 4, and the first trench groups 2 and the second trench groups 4 are arranged in a criss-cross manner.

In these two embodiments, at least part of the first trenches 20 in the first trench groups 2 communicate with each other through the communication trench portion 3, and the first trench groups 2 and the second trench groups 4 are arranged in a criss-cross manner, further ensuring that the overall structural stress of the substrate 1 is low, especially the warpage of the substrate 1 in the direction perpendicular to the first direction X is also reduced, the overall warpage of the substrate 1 is lower, and the surface flatness of the substrate is better.

As an embodiment, the ratio of the number of the first trench groups 2 to the number of the second trench groups 4 in the substrate 1 is close to 1, the first trench groups 2 and the second trench groups 4 are arranged in a criss-cross manner, and at least part of the first trenches 20 in the first trench groups 2 communicate with each other through the communication trench portion 3. The ratio of the numbers being close to 1 can further reduce the overall structural stress of the substrate 1 and ensure the surface flatness and warpage of the substrate 1.

With continued reference to FIG. 2, the second trench group 4 includes a plurality of second trenches 40. As an example, the second trench 40 is in the form of a rectangular trench, the plurality of second trenches 40 of each second trench group 4 are parallel to each other, and each second trench 40 extends in the first direction X. Other embodiments are also possible for the shape and extension direction of the second trench 40, for example, the second trench 40 is in the shape of a circular arc-shaped trench or a wavy trench (not shown). It will be understood that an example is shown in FIG. 2, and the implementation is not particularly limited.

Referring to FIG. 3, in the third direction Y, a first gap 61 is formed between adjacent second trench groups 4, and the dimension is D1 as shown in the FIG. 3; in the first direction X, a second gap 62 is formed between adjacent second trench group 4 and first trench group 2, and the dimension is D2 as shown in the FIG. 3; the dimension D1 of the first gap 61 is greater than the dimension D2 of the second gap 62. As an example, as shown in FIG. 3, the second trench 40 is in the form of a rectangular trench, the plurality of second trenches 40 of each second trench group 4 are parallel to each other, and each second trench 40 extends in the first direction X. In this case, the first gaps 61 between adjacent second trench groups 4 are of a unique dimension and are equal in the third direction Y, that is, two second trenches 40 of adjacent second trench groups 4 at adjacent positions are parallel. Other embodiments are provided for the shape and extension direction of the second trench 40, for example, the second trench 40 is in the shape of a circular arc-shaped trench or a wavy trench (not shown). In this case, the first gaps 61 between adjacent second trench groups 4 are not of a unique dimension and may be unequal in the third direction Y.

In the embodiment, the dimension D1 of the first gap 61 is greater than the dimension D2 of the second gap 62, but it should be understood that the second gap 62 does not limit the first gap 61. The dimension D1 of the first gap 61 is greater than the dimension D2 of the second gap 62, that is, the space of the first gap 61 is greater than the space of the second gap 62, such that it is more convenient and more flexible to subsequently arrange other interconnection structures at the position of the first gap 61; for example, the arrangement and size setting of the interconnection structures are more flexible. It should be understood by those skilled in the art that other interconnection structures may be arranged in the space of the second gap 62, and the embodiment is not limited thereto.

With continued reference to FIG. 3, the second trench 40 is in the form of a rectangular trench, the plurality of second trenches 40 of each second trench group 4 are parallel to each other, and each second trench 40 extends in the first direction X. In the third direction Y, the second trench group 4 includes side surfaces at edges thereof, which are in the form of sides in the top view. Since the second trench 40 is in a rectangular shape, the sides are straight lines extending in the first direction X. In the third direction Y, the first gap 61 is formed between adjacent second trench groups 4, and in this case, the dimensions D1 of the first gaps 61 between adjacent second trench groups 4 are the same.

In the embodiment, the end part of the first trench 20 is provided with an end surface, and the end surfaces of the plurality of first trenches 20 of each first trench group 2 are flush in the first direction X. For example, in the third direction Y, a plurality of end surfaces located at the upper end of the first trenches 20 are flush, or a plurality of end surfaces located at the lower end of the first trenches 20 are flush.

As an example, the first trench 20 is in the form of a rectangular trench, the plurality of first trenches 20 of each first trench group 2 are parallel to each other, and each first trench 20 extends in the third direction Y. The rectangular trench has a long side and a wide side, the first trench 20 is provided with an end surface on the wide side, and a plurality of end surfaces on the same side in the third direction Y are flush.

In the embodiment, the second trench group 4 is provided with the side surfaces of the edges of the second trenches 40 at the edges thereof. Since the first trenches 20 are provided with the plurality of end surfaces that are flush on the same side in the third direction Y, the side surfaces and the end surfaces are also flush in the first direction X. Alternatively, adjacent first trench group 2 and second trench group 4 are provided in the third direction Y. The first trenches 20 are provided with the plurality of end surfaces that are flush on the same side in the third direction Y, the second trench group 4 is provided with the side surfaces at edges thereof, and a third gap 63 is formed between the side surface and the end surface in the third direction Y. As shown in FIG. 3, the dimension D1 of the first gap 61 is equal to the dimension D3 of the third gap 63. The position of the third gap 63 provides more room for arranging other interconnection structures subsequently. It will be understood that the dimension D1 of the first gap 61 and the dimension D3 of the third gap 63 may be equal or unequal, for example, D1 is greater than D3. An example is given herein, and the implementation is not particularly limited.

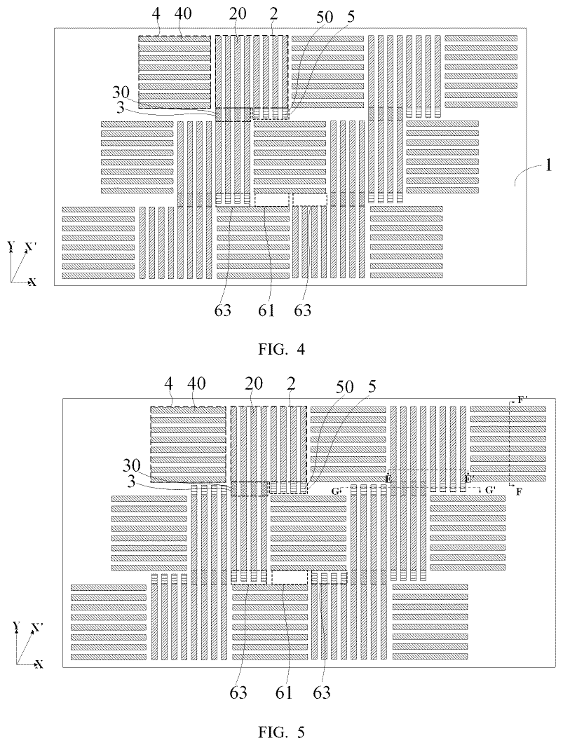

Referring to FIG. 4, the semiconductor structure further includes extension trench portions 5. Each of the extension trench portions 5 is arranged in the third gap 63, and the extension trench portion 5 is connected to the first trench group 2; the extension trench portion 5 includes a plurality of extension trenches 50, and each of the extension trenches 50 communicates with each of the first trenches 20.

As an example, the first trench 20 is in the form of a rectangular trench, the plurality of first trenches 20 of each first trench group 2 are parallel to each other, and each first trench 20 extends in the third direction Y. The extension trench 50 is in the form of a rectangular trench, the plurality of extension trenches 50 of each extension trench portion 5 are parallel to each other, and each extension trench 50 extends in the third direction Y. When the extension trench portion 5 is connected to the first trench group 2, corresponding extension trenches 50 and first trenches 20 are in communication, and the extension trenches 50 and the first trenches 20 being in communication are aligned collinearly in the third direction Y.

Other embodiments are also possible for the shape and extension direction of the first trench 20 and the extension trench 50, for example, the first trench 20 and the extension trench 50 may be in the shape of a circular arc-shaped trench or a wavy trench (not shown). When the extension trench portion 5 is connected to the first trench group 2, the corresponding extension trenches 50 and first trenches 20 are connected, and the two communicate with each other at the connecting point. It will be understood that an example is shown in FIG. 4, and the implementation is not particularly limited.

In the embodiments of the present disclosure, the presence of the communication trench portions 3 and the extension trench portions 5 may increase the spatial proportion of the trenches in the substrate 1 (or interposer or Si interposer) to the substrate 1, and increase the specific surface area (the ratio of the sum of the surface areas of the side walls and the bottoms of the trenches to the sum of the volumes of the trenches) of the trench structure in the substrate 1. As a result, the capacitance density (the capacitance per unit area in the top view) of the silicon capacitor manufactured in the substrate 1 is higher. It should be noted that the communication trench portion 3 is connected to the first trench group 2, which firstly ensures a lower structural stress of the substrate 1, and secondly increases the capacitance density of the silicon capacitor in the substrate 1.

In the embodiment, the extension trench portion 5 communicates with the first trench group 2; since the feature dimension (such as length and width) of the extension trench portion 5 is usually relatively small, if the extension trench portion does not communicate with the first trench group 2, the process manufacturing becomes more difficult. Therefore, the extension trench portion 5 communicating with the first trench group 2 is an example, and the implementation is not particularly limited. That is, the semiconductor structure includes the extension trench portion 5, the extension trench portion 5 is located between the first trench group 2 and the second trench group 4 adjacent in the third direction Y, and the extension trench portion 5 and the first trench group 2 may or may not be in communication.

In another embodiment, as shown in FIG. 5, the extension trench portion 5 is arranged in the third gap 63. Two adjacent sides of the first gap 61 are respectively provided with a third gap 63, and the extension trench portion 5 may be arranged in both of the third gaps 63, or may be arranged in only one of the third gaps 63 as shown in FIG. 4; or arranged according to actual needs, for increasing the capacitance density of the silicon capacitor in the substrate 1.

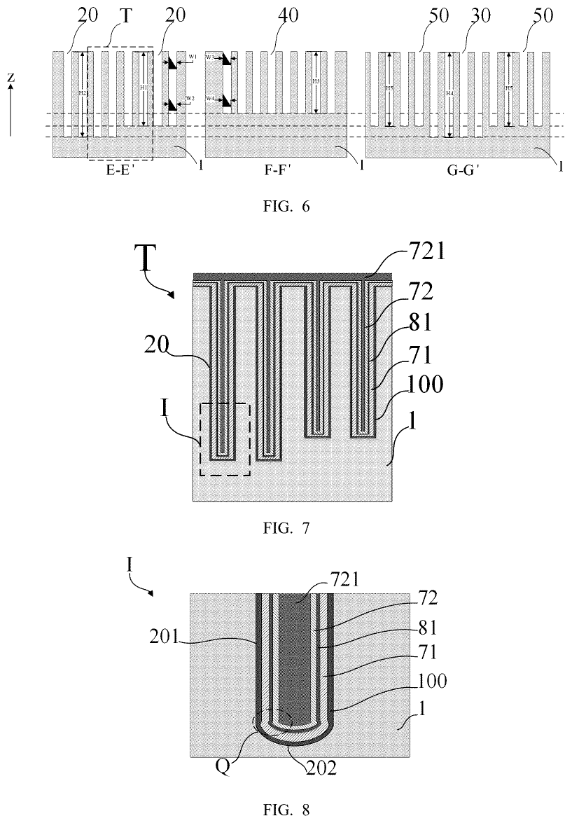

FIG. 6 is a cross-sectional view of the substrate 1 in E-E′, F-F′, and G-G′ directions in FIG. 5, where the cross-sectional view in the E-E′ direction is a cross-section of the first trench group 2, the cross-sectional view in the F-F′ direction is a cross-section of the second trench group 4, and the cross-sections in the G-G′ direction are those of the extension trench portion 5, the communication trench portion 3, and the extension trench portion 5 from left to right, respectively. The section in the E-E′ direction is proximal to the cross-section in the G-G′ direction.

As an example, as shown in FIG. 5, the top views of the extension trench 50, the communication trench 30, the second trench 40, and the first trench 20 are in the form of a rectangular trench, and the widths of the rectangles are substantially consistent. Referring to FIG. 6, for each trench, the widths of the top and the bottom of the rectangle are substantially consistent in the depth direction Z. The positions of the top and the bottom are conceptually relative positions with respect to the middle depth position of each trench, and the specific positions are not limited.

In the present disclosure, being substantially consistent or approximately equal means that the dimensions may be completely identical or may be substantially consistent within a certain tolerance range, e.g., a preset tolerance range, and the specific tolerance value may be determined by combining actual processing requirements.

As shown in FIG. 6, the top and the bottom of the first trench 20 have a first width W1 and a second width W2, respectively, and the first width W1 is substantially consistent with the second width W2. The top and the bottom of the second trench 40 have a third width W3 and a fourth width W4, respectively, and the third width W3 is substantially consistent with the fourth width W4. In the embodiment, the first width W1 is also substantially consistent with the third width W3, the preferred range of the first width and the third width is from 0.2 μm to 1.6 μm, and may be any dimension of 0.2 um, 0.3 um, 0.5 μm, 0.9 um, 1.2 um, 1.5 μm, 1.6 um, or may be other range greater than 1.6 μm or less than 0.2 um. Under the preferred conditions of the embodiment, the capacitance density of the silicon capacitor obtained from 0.2 μm to 1.6 um is high.

In the present disclosure, the widths of the top and the bottom of the trench are substantially consistent, which allows for easier subsequent filling of the capacitor material, resulting in good continuity and thickness consistency of the filled capacitor material. Therefore, the capacitance density of the silicon capacitor is high, and the leakage current is low.

With continued reference to FIG. 6, the depth of the embodiment is in the fourth direction, namely Z direction.

In the cross-sectional view in the E-E′ direction, the plurality of first trenches 20 of the first trench group 2 have different depths; the first trench 20 has a first depth H1 proximal to the position where the first trenches 20 communicate with the extension trench portion 5, and the first depths H1 of a plurality of first trenches 20 are substantially consistent; the first trench 20 has a second depth H2 proximal to the position where the first trenches 20 communicate with the communication trench portion 3, and the second depths H2 of a plurality of first trenches 20 are substantially consistent; the second depth H2 is greater than the first depth H1.

In the cross-sectional view in the F-F′ direction, the second trench 40 of the second trench group 4 has a third depth H3, and the third depths H3 of the plurality of second trenches 40 are substantially consistent.

In the cross-sectional view in the G-G′ direction, fourth depths H4 of the plurality of communication trenches 30 of the communication trench portion 3 are substantially consistent, and fifth depths H5 of a plurality of extension trenches 50 of the extension trench portion 5 are substantially consistent.

As indicated by the dashed lines in FIG. 6, the third depth H3 has a minimum depth; the first depth H1 and the fifth depth H5 are substantially consistent and both are greater than the third depth H3; the second depth H2 and the fourth depth H4 are substantially consistent and both are greater than the first depth H1.

In the present disclosure, the second trench group 4 (corresponding to the third depth H3), the extension trench portion 5 (corresponding to H5), the first trench group 2 (corresponding to H1 and H2), and the communication trench portion 3 (corresponding to H4) are etched to form trenches, and a structure in which the depths of the second trench 40, the extension trench 50, the first trench 20, and the communication trench 30 are sequentially increased may be formed. It will be understood that if there is no communication trench portion 3 and extension trench portion 5, the depths of the trenches formed by synchronously etching the second trench group 4 and the first trench group 2 may be substantially consistent, but in the embodiment, the presence of the communication trench portion 3 and the extension trench portion 5 increases the depth of the first trench group 2 compared with the previous depth, thereby increasing the capacitance density of the silicon capacitor.

The present disclosure further provides a semiconductor device. The semiconductor device includes: any one of the semiconductor structures disclosed above and a capacitor stack stacked in the semiconductor structure. The capacitor stack extends continuously along the side walls and the bottom surfaces of the first trench groups 2 and the communication trench portions 3; or the capacitor stack extends continuously along the side walls and the bottom surfaces of the first trench groups 2, the communication trench potions 3, and the second trench groups 4; or the capacitor stack extends continuously along the side walls and the bottom surfaces of the first trench groups 2, the communication trench portions 3, the second trench groups 4, and the extension trench portions 5.

In one embodiment, the semiconductor structure includes: a substrate 1; first trench groups 2 located in the substrate 1, where at least two first trench groups 2 are arranged in a second direction X′, and the first trench group 2 includes a plurality of first trenches 20; and communication trench portions 3 communicating with adjacent first trenches 20 in a third direction Y.

In one embodiment, the semiconductor structure further includes: second trench groups 4 located in the substrate 1, where a plurality of second trench groups 4 are arranged in a first direction X. The second trench groups 4 and the first trench groups 2 are arranged in an array, and two second trench groups 4 arranged in the first direction X are separated by the first trench group 2.

In one embodiment, the semiconductor structure further includes: extension trench portions 5. The extension trench portion 5 is connected to the first trench group 2; the extension trench portion 5 includes a plurality of extension trenches 50, and the extension trenches 50 communicate with the first trenches 20.

As an example, the capacitor stack is a three-layer structure including a lower electrode layer, a dielectric layer, and an upper electrode layer, or a five-layer structure including an electrode layer 1, a dielectric layer 1, an electrode layer 2, a dielectric layer 2, and an electrode layer 3, or a stack structure of more layer structures. Each electrode layer may be a single-layer or multi-layer sub-electrode layer, or may be a layered structure or a composite structure composed of a plurality of same or different sub-electrode layers. Each dielectric layer may be a single-layer or multi-layer sub-dielectric layer, or may be a layered structure or a composite structure composed of a plurality of same or different sub-dielectric layers.

The material of the electrode layer may be a metal or a conductive nonmetal, and the material of the dielectric layer may be an insulator or a semiconductor. For example, the material of the electrode may be one or more of tungsten, copper, aluminum, gold, silver, titanium nitride, and doped polycrystalline silicon, and the material of the dielectric layer may be one or more of aluminum oxide, titanium oxide, zirconium oxide, hafnium oxide, lanthanum oxide, niobium oxide, and the like.

Referring to FIG. 7, taking several first trenches 20 of the first trench group 2 in the T region as shown in FIG. 6 as an example, the capacitor stack extends continuously along the side walls and the bottom surfaces of the first trenches 20, and the capacitor stack includes a lower electrode 71, a dielectric layer 81, and an upper electrode 72. The lower electrode 71, the dielectric layer 81, and the upper electrode 72 sequentially and continuously cover the side walls and the bottom surfaces of the first trenches 20, and each of the lower electrode 71, the dielectric layer 81, and the upper electrode 72 further continuously or discontinuously covers the top surface between corresponding trenches; the top surface is in the surface in the top view of the substrate 1. The capacitor stack shows three layers, namely the lower electrode 71, the dielectric layer 81, and the upper electrode 72, and actually have more layer structures. For example, a dielectric layer and an electrode layer may be stacked on the lower electrode 71, the dielectric layer 81, and the upper electrode 72 to form a capacitor stack of a five-layer or more-layer stack structure. The greater the number of layers, the higher the capacitance density; however, leakage current, process difficulty, cost, and the like are correspondingly increased, and thus a controllable balance needs to be found, which is not limited herein.

The upper electrode and the lower electrode may be a single-layer conductive material structure, or may be a multi-layer electrode structure of the same or different conductive materials, or may be an electrode structure of a composite conductive material composed of different conductive materials, which is not limited herein. Similarly, the dielectric layer may be a layer of high-k (high-k) material, or may be a multi-layer dielectric layer structure of the same or different dielectric materials, or a dielectric layer structure of a composite dielectric material composed of different dielectric materials, which is not limited herein.

Before arranging the lower electrode 71, at least one insulating layer 100 is further arranged on the side walls and the bottom surface of the first trench 20 or the entire surface of the trench for preventing metal diffusion or improving leakage current at the side walls of the trench; the material of the insulating layer 100 may be one or more of silicon oxide, silicon nitride, silicon carbonitride, and silicon oxynitride, or may be one or more of tantalum, tantalum nitride, titanium nitride, and tungsten nitride.

After the dielectric layer 81, the upper electrode 72 may continuously cover the side walls and the bottom surface of the first trench 20, and then a supplemental electrode layer 721 fills the trench space remaining in the first trench 20; alternatively, the upper electrode 72 may directly fill the first trench 20.

As shown in FIGS. 6 and 7, since the widths of the top and the bottom of the trench are substantially consistent, when the capacitor stack extends continuously along the side walls and the bottom surface of the first trench 20 (as an example), the continuity of the material layers of the lower electrode 71, the dielectric layer 81, and the upper electrode 72 is good, that is, the layers of the capacitor stack may continuously cover the side walls and the bottom surface of the trench, and the defects are few; the thickness of each layer of the capacitor stack at the top and the bottom of the trench has good uniformity and can be substantially consistent, resulting in a silicon capacitor with high capacitance density and low leakage current.

As an example, referring to FIG. 8, FIG. 8 is an enlarged view of the region I in FIG. 7, and the region I has a region Q at a position where the side wall 201 and the bottom surface 202 of the first trench 20 are connected. As shown in FIG. 8, the lower electrode 71, the dielectric layer 81, and the upper electrode 72 each have a protrusion at the position of the region Q, that is, the layers of the capacitor stack are recessed inward toward the insulating layer 100 at the position of Q. For example, the material layer of the lower electrode 71 has different widths at different positions of the first trench 20, the widths of the material layer at the top and the bottom of the trench are substantially consistent, while the width at the position of Q is increased. The first trench 20 is taken as an example in the embodiment, and protrusions may be formed at positions where the side walls and the bottom surfaces of other trenches of the semiconductor device of the present disclosure are connected. At these connecting positions, the thickness of each layer of the capacitor stack may be discontinuous and even have defects of fractures and holes. However, the arrangement of protrusions improves the thickness continuity and consistency of the capacitor stack at the positions, resulting in a lower leakage current of the silicon capacitor.

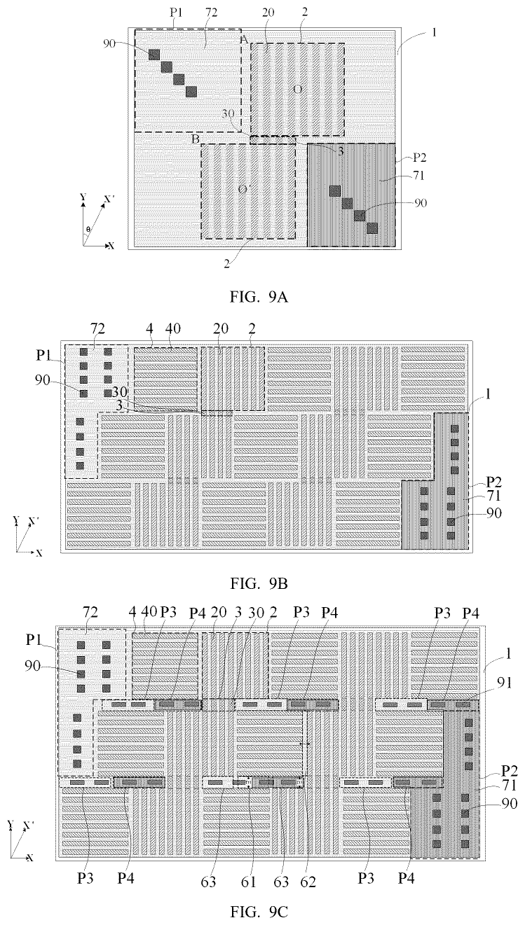

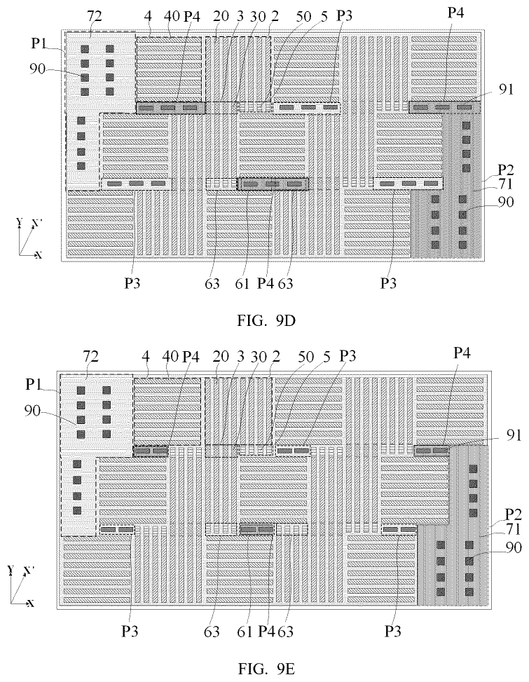

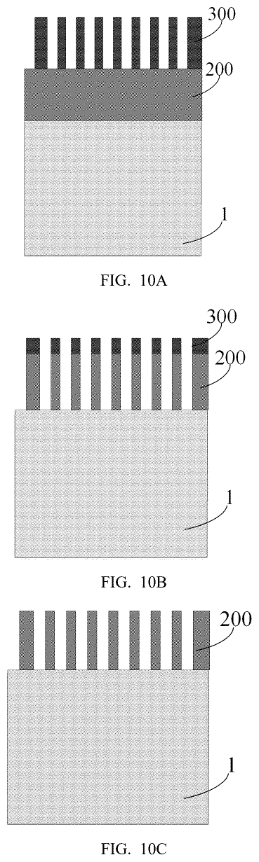

Referring to FIGS. 9A and 9B, the semiconductor device further includes: first contact plugs 90; one end of a plurality of first contact plugs 90 is connected to the upper electrode 72 or the lower electrode 71, and the other end of the plurality of first contact plugs is connected to other external conductive structures.

As shown in FIGS. 9A and 9B, the plurality of first contact plugs 90 are distributed in the edge regions (e.g., the P1 region and P2 region shown in FIG. 9A) of the substrate 1, and in these regions, no trench is formed in the substrate 1. The upper electrode 72 or the lower electrode 71 may continuously or discontinuously cover these regions. For a clearer view, the upper electrode 72 is shown in a translucent manner. Only the lower electrode 71 is exposed in the P2 region of the substrate 1, without the dielectric layer or the upper electrode thereon; however, only the upper electrode 72 may be provided in the P1 region without the dielectric layer and the lower electrode, or not only the upper electrode 72 but also the dielectric layer 81 and the lower electrode 72 (not shown) may be provided. In other regions except the P1 region and the P2 region on the substrate 1, there are not only the upper electrode 72 but also the dielectric layer 81 and the lower electrode 72. In the P1 region and the P2 region, the plurality of first contact plugs 90 are electrically connected to the upper electrode 72 and the lower electrode 71 separately. The first contact plugs 90 are arranged in the edge non-trench regions of the substrate 1, and the upper electrode 72 or the lower electrode 71 is directly exposed in the edge region, or only one of the upper electrode or the lower electrode is provided in the edge region. The lower electrode 71 can be electrically connected to the first contact plug 90 without opening a window at a later stage. That is, there is no need to etch and open the upper electrode or the dielectric layer to form a window for the first contact plug 90, thereby avoiding damage to the lower electrode caused by the failure to accurately stop on the lower electrode when opening the window, and thus ensuring a simple and reliable process.

As an example, when the lower electrode 71, the dielectric layer 81, and the upper electrode 72 each continuously cover the top surface between the trenches and the surface of the substrate 1, all the first contact plugs 90 connected to the upper electrode 72 are led out perpendicularly and then connected to each other, and all the first contact plugs 90 connected to the lower electrode 71 are led out perpendicularly and then connected to each other, thereby maximizing the capacitance of the silicon capacitor.

In some other embodiments, when the lower electrode 71, the dielectric layer 81, and the upper electrode 72 each discontinuously cover the top surface between the trenches and the surface of the substrate 1, the first contact plugs 90 can be electrically connected in different ways to adjust the capacitance of each trench capacitor, or form a plurality of trench capacitors in parallel or series.

In these embodiments, the capacitor stack is shown to include the lower electrode 71, the dielectric layer 81, and the upper electrode 72 only. If there are more layers of the capacitor stack, for example, five layers, seven layers, or more, in this case, the plurality of first contact plugs 90 are arranged in different regions with one end connected to different electrode layers in the capacitor stack. Therefore, the examples do not constitute a limitation on the number of electrode layers in the capacitor stack and the position where the electrode layer is connected to the first contact plug 90.

Referring to FIG. 9C, the semiconductor device further includes: second contact plugs 91; one end of a plurality of second contact plugs 91 is connected to the upper electrode 72 or the lower electrode 71, and the other end of the plurality of second contact plugs is connected to other external conductive structures.

As shown in FIG. 3, in the embodiment, a third gap 63 is formed between the first trench group 2 and the second trench group 4.

As shown in FIG. 9C, the plurality of second contact plugs 91 are uniformly distributed at the positions of the first gaps 61 and the third gaps 63; the upper electrode 72 or the lower electrode 71 may continuously or discontinuously cover the first gaps 61 and the third gaps 63. To electrically isolate the upper electrode 72 from the lower electrode 71, the positions of the first gaps 61 and the third gaps 63 may have only the upper electrode 72 in some regions (the P3 regions as shown in FIG. 9C), and only the lower electrode 71 in some regions (the P4 regions as shown in FIG. 9C), and the plurality of second contact plugs 91 are electrically connected to the upper electrode 72 and the lower electrode 71 separately; in the region P3, the dielectric layer 81 and the lower electrode 71 are sequentially arranged below the upper electrode 72, which are not shown in the figure. The connection relationship between the second contact plug 91 and the upper electrode 72 or the lower electrode 71 at the positions of the first gap 61 and the third gap 63 is provided as exemplary. For example, the second contact plug 91 in the P3 region is connected to the upper electrode 72, and the second contact plug 91 in the P4 region is connected to the lower electrode 71. However, this does not constitute a specific limitation, and those skilled in the art may flexibly set the connection relationship according to actual needs.

As an example, all the second contact plugs 91 connected to the upper electrode 72 (the second contact plugs 91 in the P3 regions as shown in FIG. 9C) are led out perpendicularly and then connected to each other, and connected to the first contact plugs 90 in the P1 region, and all the second contact plugs 91 connected to the lower electrode 71 (the second contact plugs 91 in the P4 regions as shown in FIG. 9C) are led out perpendicularly and then connected to each other, and are connected to the first contact plugs 90 in the P2 region, thereby maximizing the capacitance of the silicon capacitor.

By arranging the second contact plugs 91 at the positions of the first gaps 61 and the third gaps 63, more and shorter conductive paths are additionally provided, the resistance of the interconnection structure is greatly reduced, and the equivalent resistance of the whole silicon capacitor is reduced, thereby reducing the leakage current.

Similarly, in some embodiments, as shown in FIG. 4, the third gap 63 are formed between the first trench group 2 and the second trench group 4; or as shown in FIG. 5, the third gap 63 is formed between the first trench group 2 and the second trench group 4. In FIGS. 9D and 9E, the plurality of second contact plugs 91 are uniformly distributed at the positions of the first gaps 61 and the third gaps 63; the upper electrode 72 or the lower electrode 71 may continuously or discontinuously cover these regions. When the extension trench portion 5 is provided at the position of the third gap 63, the second contact plug 91 may not be arranged at the position, as it may need to open the windows of the upper electrode 72 and the dielectric layer 81 in this case. Alternatively, only the second contact plug 91 is arranged at the position of the third gap 63 with the extension trench portion 5, and the second contact plug 91 is connected to the upper electrode (not shown), which does not involve opening the windows of the upper electrode 72 and the dielectric layer 81.

The present disclosure further provides a method for forming a semiconductor device. The method includes: providing a substrate 1; forming first trench groups 2, second trench groups 4, and communication trench portions 3 in the substrate 1; and forming a capacitor stack, where the capacitor stack is stacked on the first trench groups 2, the second trench groups 4, and the communication trench portions 3, and the capacitor stack extends continuously along the side walls 201 and the bottom surfaces 202 of the first trench groups 2, the second trench groups 4, and the communication trench portions 3.

At least two first trench groups 2 are arranged in a second direction; the first trench group 2 includes first trenches 20; the communication trench portion 3 communicates with adjacent first trenches 20 in a third direction; a plurality of second trench groups 4 are arranged in a first direction. The second trench groups 4 and the first trench groups 2 are arranged in an array, and two second trench groups 4 are separated by the first trench group 2 in the first direction; the first direction, the second direction, and the third direction are located in the same plane, the first direction is perpendicular to the third direction, the second direction intersects with the first direction and the third direction, and an included angle between the second direction and the third direction is an acute angle.

The method includes the following steps:

In Step 1, a substrate 1 is provided.

The provided substrate 1 is provided with opposite front surface and back surface, the front surface and the back surface being parallel to each other. The substrate 1 may be provided with a circuit structure on the back surface; the circuit structure may include, but is not limited to, a device layer, a metal interconnect layer, a dielectric layer, and the like.

In Step 2, first trench groups 2, second trench groups 4, and communication trench portions 3 are formed on the front surface of the substrate 1.

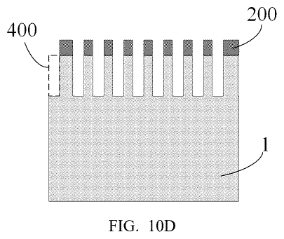

The method includes the following steps: As shown in FIGS. 10A to 10D, first, a sacrificial layer 200 of a certain thickness and a mask layer 300 of a certain thickness are sequentially formed on the surface of the substrate 1; then, part of the mask layer 300 is removed by photoetching, and the mask layer 300 after photoetching is formed by taking the top views of the first trench group 2, the second trench group 4, and the communication trench portion 3 as patterns; next, the sacrificial layer 200 is etched by taking the mask layer 300 as a template until reaching the surface of the substrate 1; finally, the mask layer 300 is removed, and the sacrificial layer 200 continues to be taken as a template to etch downward and remove part of the material of the substrate 1, so as to form the first trench group 2, the second trench group 4, and the communication trench portion 3.

In other embodiments, forming extension trench portions 5 is further included, and the extension trench portion 5 is formed simultaneously with the first trench group 2, the second trench group 4, and the communication trench portion 3.

Removing part of the mask layer 300 further includes photoetching the mask layer 300 by taking a region of a certain width at the edge of the substrate 1 as a pattern. Finally, as shown in FIG. 10D, when the substrate 1 including the first trench groups 2, the second trench groups 4, and the communication trench portions 3 is formed, a dummy trench 400 is formed in the outer edge of the substrate 1. The dummy trench 400 is used to balance the slow etching rates of the first trench group 2 and the second trench group 4 located at the edge of the substrate 1 during etching, thereby avoiding the problem of nonuniform widths of formed trenches.

As shown in FIG. 10D, after the sacrificial layer 200 is taken as a template to etch downward and remove part of the material of the substrate 1, the sacrificial layer 200 still has a certain thickness remaining, which is less than the thickness of the initial sacrificial layer 200. The sacrificial layer 200 with a certain remaining thickness can prevent the risk that the side walls between trenches collapse due to the longer length of the trenches when forming rectangular trenches.

The method for removing part of the material of the substrate 1 includes, but is not limited to, laser etching, mechanical etching, and chemical etching, or includes, but is not limited to, wet etching, dry etching, Bosch etching, among which the Bosch etching is easier to form a trench with perpendicular side walls.

The first trench group 2, the second trench group 4, and the communication trench portion 3 may be formed by synchronous etching or asynchronous etching. The synchronous etching means that all the patterns of the first trench group 2, the second trench group 4, and the communication trench portion 3 in the sacrificial layer 200 are formed and exposed on the surface of the substrate 1, and then the same etching process parameters are used for etching, e.g., Bosch etching, in which the process parameters are the same across all positions of the substrate 1, and include etching gas concentration, plasma concentration, speed, and the like. For example, during laser etching, the process parameters are the same across all positions of the substrate 1; for example, the laser is perpendicular to the surface of the material of the substrate 1, and the laser energy and time are the same. During synchronous etching, if the dimension features of the structures are the same, for example, as seen from the top view, the diameter of a plurality of circular holes is the same, or the length and width features (or length multiplied by width) of a rectangle are the same, where the circular hole or rectangle refers to the shape of the trench in the top view direction, the depths of trenches formed by etching in the same time may be the same. However, in the embodiment, due to the presence of the communication trench portion 3, which communicates with adjacent first trench groups 2, trenches of different depths may be formed after the first trench group 2 and the second trench group 4 are simultaneously and synchronously etched, as shown in FIG. 6.

The trenches of the first trench group 2, the second trench group 4, the communication trench portion 3, and the extension trench portion 5 are each provided with corresponding side walls 201 and bottom surfaces 202 of the same or similar structures, and the widths of the side wall 201 at different depth positions may be substantially consistent; the bottom surface 202 may be a horizontal bottom surface or a circular arc bottom surface recessing downward, as shown in FIG. 8.

The material of the mask layer 300 includes, but is not limited to, one or a combination of more of polycrystalline silicon, photoresist, metal film, polyimide, and the like; the material of the sacrificial layer 200 includes, but is not limited to, one or a combination of more of silicon nitride, silicon oxynitride, silicon carbide, silicon carbonitride, silicon oxycarbide, and the like.

In Step 3, a capacitor stack is deposited on the substrate 1, which includes: depositing the capacitor stack on the first trench groups 2, the second trench groups 4, and the communication trench portions 3, where the capacitor stack extends continuously along the side walls 201 and the bottom surfaces 202 of the first trench groups 2, the second trench groups 4, and the communication trench portions 3. The capacitor stack further covers the surface of the front surface of the substrate 1.

In other embodiments, the following is further included: the capacitor stack is deposited in the extension trench portions 5, and the capacitor stack extends continuously along the side walls 201 and the bottom surfaces 202 of the extension trench portions 5.

Before depositing the capacitor stack, the following is further included: as shown in FIGS. 7 and 8, one insulating layer 100 is deposited on the side walls 201 and the bottom surfaces 202 of the first trench groups 2, the second trench groups 4, and the communication trench portions 3; or the insulating layer 100 is formed by oxidation, where the insulating layer 100 of a certain thickness as a thin layer is formed by oxidizing the side walls 201 and the bottom surfaces 202 of the first trench groups 2, the second trench groups 4, and the communication trench portions 3 of the substrate 1.

The trenches of the first trench group 2, the second trench group 4, and the communication trench portion 3 are each provided with the side wall 201 and the bottom surface 202, and the insulating layer 100 has a protrusion at a position where the side wall 201 and the bottom surface 202 intersect, that is, the insulating layer 100 is recessed inward toward the substrate 1 at the intersection, as shown in FIG. 8. As another embodiment, the inward recess is formed before the insulating layer 100 is formed. For example, the trenches of the first trench group 2, the second trench group 4, and the communication trench portion 3 are each provided with the side wall 201 and the bottom surface 202, and the position where the side wall 201 and the bottom surface 202 intersect has a feature that is recessed inward toward the substrate 1, that is, the trench is recessed inward at the intersection (not shown). The protrusion can be obtained by adjusting the etching parameters of the last or several etching cycles, for example, in Bosch etching, the duration of the last or several etching cycles is prolonged to enlarge the scallop shape, and a plurality of scallop shapes form the inward recess of the trench.

The capacitor stack includes at least three layers, namely the lower electrode 71, the dielectric layer 81, and the upper electrode 72, or is a multi-layer structure consisting of more electrode layers, dielectric layers, and electrode layers. The lower electrode 71, the dielectric layer 81, and the upper electrode 72 have protrusions at the intersection between the side wall 201 and the bottom surface 202, that is, each layer of the capacitor stack is recessed inward in the horizontal direction of the substrate 1 at the intersection, as shown in FIG. 8.

When the capacitor stack covers the surface of the front surface of the substrate 1, the lower electrode 71 continuously extends to cover the surface of the front surface of the substrate 1; the dielectric layer 81 discontinuously extends to cover the surface of the front surface of the lower electrode 71, and the discontinuous region may expose the lower electrode 71 for manufacturing contact plugs subsequently; the upper electrode 72 discontinuously extends to cover the surface of the front surface of the dielectric layer 81, and the upper electrode 72 covers the dielectric layer 81, that is, the patterns of the two are the same. As shown in FIGS. 9A to 9E, the discontinuous region of the upper electrode 72 is the same as the discontinuous region of the dielectric layer 81. In this step, the lower electrode 71 of the formed capacitor stack is already exposed on the surface of the front surface of the substrate 1. That is, there is no need to etch and open the upper electrode or the dielectric layer to form a window for a first contact plug 90, thereby avoiding damage to the lower electrode caused by the failure to accurately stop on the lower electrode when opening the window, and thus ensuring a simple and reliable process.

In Step 4, first contact plugs 90 and second contact plugs 91 are formed, which includes: forming the first contact plugs 90 and the second contact plugs 91 on the regions of the lower electrode 71 exposed by the dielectric layer 81. The first contact plugs 90 and the second contact plugs 91 are formed on the surface of the upper electrode 72, as shown in FIGS. 9A to 9E.

The above description is only the specific embodiments of the present disclosure, but the protection scope of the present disclosure is not limited thereto; changes or substitutions that any of those skilled in the art can easily think of within the technical scope disclosed by the present disclosure shall all fall within the protection scope of the present disclosure. Therefore, the protection scope of the present disclosure shall be defined by the protection scope of the claims.

What is claimed is:

1. A semiconductor structure, comprising:
a substrate;
first trench groups located in the substrate, wherein at least two first trench groups are arranged in a second direction, and each of the first trench groups comprises first trenches; and
communication trench portions communicating with adjacent first trenches in a third direction, wherein
the second direction and the third direction form an included angle.

2. The semiconductor structure according to claim 1, further comprising:
second trench groups located in the substrate, wherein the second trench groups are arranged in a first direction,
wherein the second trench groups and the first trench groups are arranged in an array, and every two of the second trench groups are separated by one of the first trench groups in the first direction, wherein
the first direction, the second direction, and the third direction are located in a same plane, the first direction is perpendicular to the third direction, the second direction intersects with the first direction and the third direction, and the included angle between the second direction and the third direction is an acute angle.

3. The semiconductor structure according to claim 2, wherein the first trenches extend in the third direction, each of the second trench groups comprises second trenches, and the second trenches extend in the first direction.

4. The semiconductor structure according to claim 1, wherein a number of the first trenches in each of the first trench groups is N, each of the communication trench portions comprises communication trenches, and a number of the communication trenches is greater than or equal to N/2.

5. The semiconductor structure according to claim 4, wherein the communication trenches extend in the third direction, and each of the communication trenches is collinearly aligned with first trenches vertically adjacent to the communication trench in the third direction.

6. The semiconductor structure according to claim 2, wherein a ratio of a number of the first trench groups to a number of the second trench groups is close to 1.

7. The semiconductor structure according to claim 2, wherein in the third direction, each of the second trench groups comprises side surfaces at edges thereof, and each of the first trench groups comprises a plurality of end surfaces at end parts of the first trenches; and the side surfaces and the end surfaces are flush in the first direction.

8. The semiconductor structure according to claim 2, wherein in the third direction, a first gap is formed between two adjacent second trench groups; in the first direction, a second gap is formed between adjacent second trench group and first trench group; and a dimension of the first gap is greater than a dimension of the second gap.

9. The semiconductor structure according to claim 8, further comprising extension trench portions each connected to one of the first trench groups, wherein each of the extension trench portions comprises extension trenches extending in the third direction, and the extension trenches and part of the first trenches are in communication and aligned collinearly in the third direction.

10. The semiconductor structure according to claim 3, wherein a top and a bottom of each of the first trenches have a first width and a second width, respectively, and a top and a bottom of each of the second trenches have a third width and a fourth width, respectively, the first width and the second width being substantially consistent, and the third width and the fourth width being substantially consistent.

11. The semiconductor structure according to claim 10, wherein the first width and the third width are in a range of 0.2 μm to 1.6 um.

12. The semiconductor structure according to claim 2, wherein each of the first trenches has a first depth, and each of the second trenches has a third depth, the first depth being greater than the third depth.

13. A semiconductor device, comprising:
a substrate;
first trench groups located in the substrate, wherein at least two first trench groups are arranged in a second direction, and each of the first trench groups comprises first trenches;
communication trench portions communicating with adjacent first trenches in a third direction, wherein
second trench groups located in the substrate, wherein the second trench groups are arranged in a first direction, wherein the second trench groups and the first trench groups are arranged in an array, and every two of the second trench groups are separated by one of the first trench groups in the first direction; and
a capacitor stack stacked on the first trench groups, the second trench groups, and the communication trench portions, wherein the capacitor stack extends continuously along side walls and bottom surfaces of the first trench groups, the second trench groups, and the communication trench portions, wherein
the first direction, the second direction, and the third direction are located in a same plane, the first direction is perpendicular to the third direction, the second direction intersects with the first direction and the third direction, and the included angle between the second direction and the third direction is an acute angle.

14. The semiconductor device according to claim 13, wherein the capacitor stack has protrusions at positions where the side walls and the bottom surfaces intersect.

15. The semiconductor device according to claim 13, further comprising first contact plugs, wherein the capacitor stack comprises an upper electrode and a lower electrode, the first contact plugs are located in edge regions of the substrate, and each of the edge regions is provided with one of the upper electrode or the lower electrode.

16. The semiconductor device according to claim 13, further comprising second contact plugs, wherein in the third direction, a first gap is formed between two adjacent second trench groups; in the third direction, a third gap is formed between adjacent first trench group and second trench group; and the second contact plugs are located in the first gaps and the third gaps.

17. A method for forming a semiconductor device, comprising:
providing a substrate;
forming first trench groups, second trench groups, and communication trench portions in the substrate; and
forming a capacitor stack, wherein the capacitor stack is stacked on the first trench groups, the second trench groups, and the communication trench portions, and the capacitor stack extends continuously along side walls and bottom surfaces of the first trench groups, the second trench groups, and the communication trench portions.

18. The method for forming a semiconductor device according to claim 17, further comprising forming a dummy trench at an outer edge of the substrate when forming the first trench groups, the second trench groups, and the communication trench portions in the substrate.

19. The method for forming a semiconductor device according to claim 17, wherein the capacitor stack forms protrusions at positions where the side walls and the bottom surfaces intersect.

20. The method for forming a semiconductor device according to claim 17, further comprising forming an upper electrode, a dielectric layer, and a lower electrode when forming the capacitor stack, wherein the lower electrode continuously extends to cover a surface of the substrate, and the upper electrode and the dielectric layer discontinuously extend to cover the surface of the substrate.
